(19) United States
(12) Patent Application Publication
(10) Pub. No.: US 2026/0231520 A1
(43) Pub. Date: Aug. 6, 2026

(54) SEMICONDUCTOR DEVICES WITH REDUCED CELL SIZE WHILE MAINTAINING SAME EFFECTIVE CHANNEL WIDTHS

(71) Applicant: Taiwan Semiconductor Manufacturing Company, Ltd., Hsin-Chu (TW)

(72) Inventors: Chia-Hung Chou, Hsinchu City (TW); Ka-Hing Fung, Zhudong Township (TW); Shiao-Shin Cheng, Hsinchu (TW); Jian-Hao Chen, Hsinchu City (TW); Chien-Tai Chan, Hsinchu City (TW)

(21) Appl. No.: 19/045,979

(22) Filed: Feb. 5, 2025

(51) Int. Cl. H10D 84/85

(52) U.S. Cl. CPC H10D 84/856; H10D 84/851

(57) ABSTRACT

One aspect of the present disclosure pertains to a semiconductor structure. The semiconductor structure includes a first cell having first active regions extending lengthwise along a first direction; a second cell having second active regions extending lengthwise along the first direction; and gate structures wrapping around transistor channels of the first and the second active regions to form first transistors and second transistors, respectively, the gate structures extend lengthwise across the first and the second cells along a second direction perpendicular to the first direction. Each of the first transistors include a smaller number of transistor channels than each of the second transistors, and each of the first transistors has a greater channel width than each of the second transistors.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the development of gate-all-around (GAA) field effect transistors (FETs). GAA FETs refer to transistors having gate stacks (gate electrodes and gate dielectric layers) surrounding transistor channels, such as vertically-stacked gate-all-around horizontal nanosheet MOSFET devices. To keep up with the scaling down of processor nodes, one challenge is to scale down devices without degrading performance and gate control of the overall device. For example, the drain-current (DC) performance characteristics of the GAA FETs, before and after scaling down, should be maintained for uniform performance and compatibility.

Therefore, although existing GAA FETs have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a semiconductor structure with cells of varied cell heights while maintaining a same or similar effective channel width, according to an embodiment of the present disclosure.

FIGS. 2A-2D illustrate cross-sectional views of a semiconductor structure cut along the lines A-A′, B-B′, C-C′, and D-D′ in FIG. 1, respectively, according to an embodiment of the present disclosure.

FIGS. 3A-3B illustrate cross-sectional views of a semiconductor structure having transistors of varied gate configurations while maintaining a same or similar effective channel width, according to an embodiment of the present disclosure.

FIGS. 4A-4B illustrate cross-sectional views of a semiconductor structure having transistors of varied channel configurations while maintaining a same or similar effective channel width, according to an embodiment of the present disclosure.

FIGS. 5A-5C illustrate cross-sectional views of a semiconductor structure having transistors of varied channel configurations while maintaining a same or similar effective channel width, according to an embodiment of the present disclosure.

FIG. 6 illustrates a semiconductor structure with cells of varied cell heights while maintaining a same or similar effective channel width, according to another embodiment of the present disclosure.

FIGS. 7A-7B illustrate cross-sectional views of a semiconductor structure having transistors of varied gate configurations for an N-type and a P-type FET, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to gate-all-around (GAA) field effect transistors (FETs) and the devices thereof, and particularly to reducing device cell size and improving gate control without adversely affecting effective capacitance and cell performance.

A challenge of reducing device cell size is to retain same performance characteristics before device scaling. To reduce device cell size, merely reducing channel widths or heights or adding/removing number of channels may adversely affect the device performance characteristics. The present disclosure provides a way to maintain same or similar device performance characteristics by maintaining same effective channel widths across transistors in a device. The effective channel width may be defined as the sum of the total lengths (perimeter) around the outside of each of the transistor channels. For example, transistors in a first device region have wider but smaller number of transistor channels (e.g., 3 channels), while transistors in a second device region has narrower but a greater number of channels (e.g., 4 channels). In this way, transistors in both device regions have a same or substantially similar effective channel width to maintain same or similar device performance. Further, due to the transistors in the second device region having more narrow channels, overall cell size can be reduced. In devices with the narrower channels, gate control (e.g., short channel effects) is also improved. However, in some embodiments, there may be a tradeoff between better short channel control and slightly worse critical dimensions loading effects. In any case, by maintaining same effective channel widths across transistors, drain-current (DC) performance characteristics is maintained (and in some cases improved) while reducing cell size in a GAA semiconductor device structure.

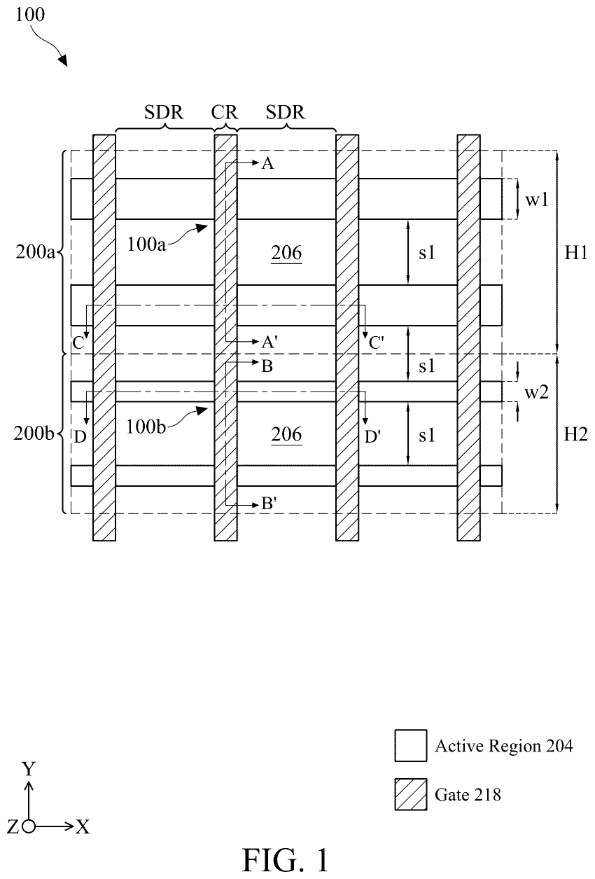

FIG. 1 illustrates a semiconductor structure 100 with cells 200a and 200b of varied cell heights while maintaining a same or similar effective channel width, according to an embodiment of the present disclosure. As described herein, the semiconductor structure 100 may correspond to a semiconductor device 100 or a portion thereof. The semiconductor structure 100 may be a portion of an integrated circuit (IC) chip, or a system on chip (SoC), that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

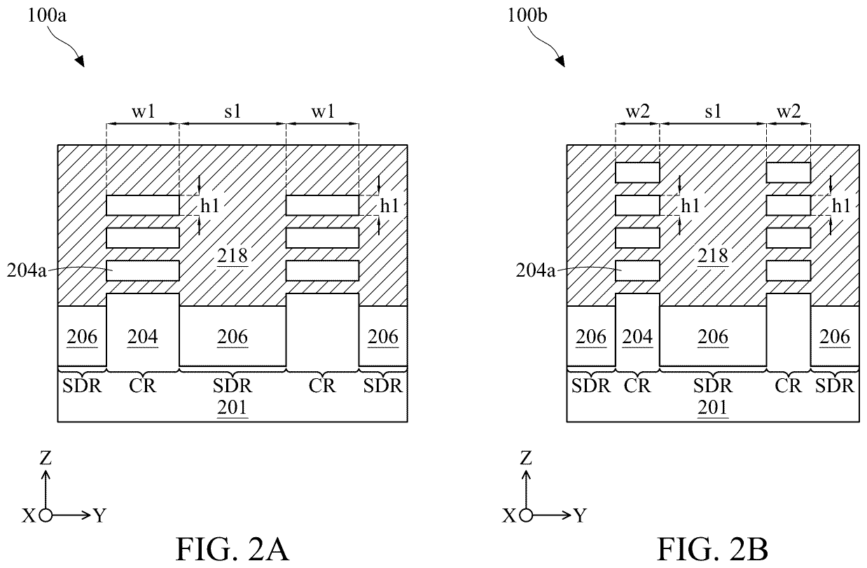

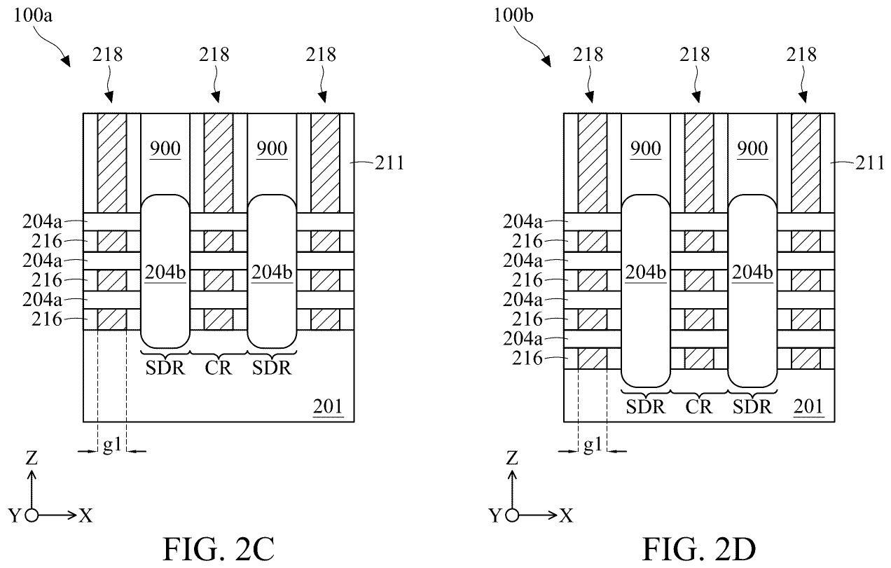

In the present embodiment, the semiconductor structure 100 illustrates a device region for ring oscillator (RO) devices. However, in alternative embodiments, the semiconductor structure 100 may illustrate device regions for other types of devices such as various memory and logic devices. As shown, the semiconductor structure 100 includes active regions 204 that extends lengthwise along the x direction and gate structures 218 that extend lengthwise along the y direction. The active regions 204 may be formed over a substrate 201 (see FIGS. 2A-2B). The substrate may be a silicon (Si) substrate, or a substrate having other semiconductor materials such as germanium (Ge), silicon carbide (SiC), silicon germanium (SiGe), or diamond. The active regions 204 may protrude above an isolation structure 206 also disposed over the substrate. The isolation structure 206 may be a shallow trench isolation (STI) layer and provides isolation between adjacent active regions 204 spaced along the Y direction. The dielectric material for the isolation structure 206 may include silicon oxide, silicon oxynitride, fluorine-doped silicate glass (FSG), a low-k dielectric, combinations thereof, and/or other suitable materials.

Each of the active regions 204 includes channel regions CR between source/drain (S/D) regions SDR. The channel regions CR include vertically stacked channels 204a (see FIGS. 2A-2B), the S/D regions include S/D epitaxial features 204b (see FIGS. 2C-2D), and the channels 204a laterally extend between the S/D epitaxial features 204b along the X direction. The S/D epitaxial features 204b may include n-type S/D features that correspond with n-type GAA transistor regions or p-type source/drain features that correspond with p-type GAA transistor regions. The S/D epitaxial features 204b may be formed by an epitaxy process using CVD deposition techniques (for example, VPE and/or UHV-CVD), molecular beam epitaxy, other suitable epitaxial growth processes, or combinations thereof. The S/D epitaxial features 204b are doped with n-type dopants and/or p-type dopants. In some embodiments, for the n-type GAA transistors, S/D epitaxial features 204b include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, S/D epitaxial features 204b include silicon germanium or germanium and can be doped with boron, other p-type dopant, or combinations thereof (for example, forming Si:Ge:B epitaxial source/drain features).

The gate structures 218 (or gate stack) are disposed over the channel regions CR of the active regions 204. The gate structure 218 engages and wraps around each of the channels 204a (see FIGS. 2A-2D). The gate structure 218 includes a gate dielectric layer (not explicitly shown) and a gate electrode (not explicitly shown) disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The metal fill layer includes a suitable conductive material, such as Al, W, and/or Cu. The metal fill layer may additionally or collectively include other metals, metal oxides, metal nitrides, other suitable materials, or combinations thereof.

The transistor channels 204a, the adjacent S/D features 204b, and the gate structure 218 collectively form transistors in the semiconductor structure 100. As shown in FIG. 1, the semiconductor structure 100 includes a first cell 200a comprising first transistors 100a and a second cell 200b comprising second transistors 100b. In the embodiment shown, the first cell 200a and the second cell 200b are adjacent to each other along the y direction. In other embodiments, the first cell 200a and second cell 200b may be interposed by other device regions. In the first cell 200a, each of the active regions 204 are spaced apart by a spacing s1 along the y direction. In the second cell 200b, each of the active regions 204 are spaced apart by a same spacing s1 along the y direction. Further, the edge active regions 204 in the first and the second cells 200a and 200b may also be spaced apart by the same spacing s1.

The first cell 200a is defined by a cell height H1 along the y direction, and the second cell 200b is defined by a cell height H2 along the y direction. Notably, the cell height H1 is greater than the cell height H2. This is because while the spacing s1 is the same between adjacent active regions 204, the active regions 204 in the first cell 200a has a greater channel width w1 along the y direction, while the active regions 204 in the second cell 200b has a smaller channel width w2 along the y direction. For example, in the depicted embodiment, the first cell 200a comprises two wider active regions 204 extending along the x direction, and the second cell 200b comprises two narrower active regions extending along the x direction. In this way, the cell height H1 is defined as two times the width w1 of the wider active regions 204 plus two times the spacing s1, and the cell height H2 is defined as two times the width w2 of the narrower active regions 204 plus two times the spacing s1. In an embodiment, the spacing s1 may be about 46nm, the channel width w1 may be about 19 nm, for a cell height H1 of about 130 nm. In an embodiment, the spacing s1 may be about 46 nm, the channel width w2 may be about 13 nm, for a cell height H2 of about 118 nm. In an embodiment, a ratio of the first cell height H1 to the second cell height H2 may be greater than about 1.1 for meaningful total device cell size reduction (when converting some of the first cells 200a into the second cells 200b). As explained in more detail below, the total device cell size may be reduced while maintaining (or improving) device performance by converting one or more first cell 200a into one or more second cells 200b.

FIGS. 2A-2D illustrate cross-sectional views of a semiconductor structure 100 cut along the lines A-A′, B-B′, C-C′, and D-D′ in FIG. 1, respectively, according to an embodiment of the present disclosure. The line A-A′ cuts along a gate structure 218 across the active regions 204 in the first cell 200a. The line B-B′ cuts along a gate structure 218 across the active regions 204 in the second cell 200b. The line C-C′ cuts along an active region 204 in the first cell 200a across multiple gate structures 218. The line D-D′ cuts along an active region 204 in the second cell 200b across multiple gate structures 218.

Referring now to FIGS. 2A and 2B, the first transistors 100a in the first cell 200a and the second transistors 100b in the second cell 200b have different number of transistor channels 204a and different channel widths (i.e., w1 versus w2). In the depicted embodiment, the first transistors 100a include three transistor channels 204a wrapped around by the gate structure 218, and the second transistors 100b include four transistor channels 204a wrapped around the gate structure 218. The transistor channels 204a are stacked above the channel region CR of the active regions 204. The channel region CR of the active regions 204 may include a protruding portion of the substrate 201 surrounded by the isolation structure 206. The first transistors 100a include transistor channels 204a having a channel width w1 and a channel height h1. The second transistors 100b include transistor channels 204a having a channel width w2 and a same (or substantially same) channel height h1. The channel width w1 is greater than the channel width w2. In an embodiment, a ratio of the first width to the second width ranges between about 1.35 to about 1.55. In an embodiment, the second width w2 ranges between about 12 nm to about 14 nm. In an embodiment, the ratio of the second width w2 to the channel height h1 is less than 3; in some embodiments, this ratio ranges between about 2.4 to about 2.8. As described and made more evident in the further details below, the ranges of dimensions/ratios of the second width w2 and height h1 is critical to ensure particular DC performance and effective capacitance.

Referring now to FIG. 1 and FIGS. 2A to 2B collectively, the spacing s1 between active regions 204 of the first transistors 100a and between the active regions 204 of the second transistors 100b are the same. The first transistor 100a are formed in the first cell 200a and the second transistors 100b are formed in the second cell 200b. Although not shown, in further embodiments, the spacing s1 between active regions 204 in the second cell 200b can be smaller than the spacing s1 between the active regions 204 in the first cell 200a. This is made possible due to the corresponding reduction of channel widths of the active regions 204 in the second cell 200b, which further improves device density. In an embodiment, the ratio of the spacing s1 to the width w2 ranges between about 3 to about 4. In an embodiment, the ratio of the spacing s1 to the channel height h1 ranges between about 8 to about 10.

Still referring to FIGS. 2A and 2B, although the first transistors 100a and the second transistors 100b have different number of transistor channels (three versus four) and also different channel widths w1 and w2, the first transistors 100a and the second transistors 100b have a same or substantially the same effective channel width. The effective channel width directly correlates with DC performance and effective capacitance. In this way, a same or substantially same DC performance and effective capacitance is maintained. Maintaining a same effective capacitance may be vital for device compatibility and uniform performance. For example, if the effective capacitance is unduly increased (e.g., by greater than 5%) when converting one or more first cells 200a into one or more second cells 200b, there is degradation in signal to noise coupling due to stray capacitance. On the other hand, if the effective capacitance is unduly decreased (e.g., by greater than 5%), there may not be enough drive current for DC gain. For the above reasons, in an embodiment, effective channel widths of first transistors 100a to be converted into second transistors 100b for reducing cell size, will not change by more than 5%.

As described herein, effective channel width is defined as the outer perimeter length of the sum of all transistor channels (N) in a transistor device (i.e., 2(h1+w1)*N). For example, the first transistors 100a have a first effective channel width defined by 2(h1+w1)*3 and the second transistors 100b have a second effective channel width defined by 2(h1+w2)*4. In an embodiment, the effective channel width across transistor devices in different regions of a cell area is less than 160 nm. In an embodiment, and as an example, the height h1 may be about 5 nm, the width w1 may be about 19 nm, and the width w2 may be about 13 nm. In this way, the first effective channel width may equal 144 nm (i.e., 2(5+19)*3), and the second effective channel width may also equal 144 nm (i.e., 2(5+13)*4). Thus, the second transistors 100b may have a smaller channel width, which reduces overall cell size, while maintaining the same performance as the first transistors 100a. Note that in some embodiments, even with the same effective channel width, the second transistors 100b may have improved gate control due to narrower channels 204a.

Referring now to FIGS. 2C and 2D, the first transistors 100a in the first cell 200a and the second transistors 100b in the second cell 200b each have gate structures 218 having a same or substantially same gate width g1 along the x direction. The gate width g1 refers to gate electrode portions of the gate structure 218 and excludes other features of the gate structure 218 (e.g., gate spacers 211 and inner spacers 216). The gate width g1 also defines the effective channel length being controlled by the gate. In an embodiment, the gate width g1 ranges between about 16 nm to about 18 nm.

In this cross-sectional view, the first transistors 100a and the second transistors 100b include S/D features 204b adjacent and interposed by the transistor channels 204a. Specifically, the source/drain regions SDR includes source/drain epitaxial features 204b that connect to transistor channels 204a of the channel regions CR. The channel regions CR underly the respective gate structures 218. The gate structures 218 may include gate spacers 211 and inner spacers 216 along sidewalls of a gate electrode. Inner spacers 216 are disposed along sidewalls of a bottom portion the gate structure 218 (e.g., below the topmost channel 204a) and gate spacers 211 are disposed along sidewalls of a top portion of the gate structure 218 (e.g., above the topmost channel 204a). Each of the inner spacers 216 are disposed vertically between channels 204a and laterally between the S/D feature 204b and the gate structure 218. Each of the gate spacers 211 land on the topmost channel 204a and may be disposed directly above the inner spacers 216. In some embodiments, the inner spacers 216 include a dielectric material that includes silicon, oxygen, carbon, nitrogen, other suitable material, or combinations thereof (for example, silicon oxide (SiO₂), silicon nitride (SiN), silicon oxynitride (SiON), silicon carbide (SiC), or silicon oxycarbonitride (SiOCN). In some embodiments, the inner spacers 216 includes a low-k dielectric material. In some embodiments, the gate spacers 211 may be made of silicon oxide (SiO₂), silicon nitride (SiN), silicon oxycarbide (SiOC), silicon oxycarbonitride (SiOCN), silicon carbonitride (SiCN), metal nitride, or a suitable dielectric material. In some embodiments, the inner spacers 216 may include a material that is different from a material of the gate spacers 211 to achieve desired etching selectivity or to achieve different isolation effects.

Still referring to FIGS. 2C and 2D, the S/D features 204b may be formed by etching S/D trenches in the S/D regions SDR, and then epitaxially growing the S/D features 204b in the S/D trenches over protruding portions of the substrate 201. The S/D trenches may be formed by a dry etching process, a wet etching process, other suitable etching process, or combinations thereof. Notably, in forming the second transistors 100b, the S/D trenches are etched deeper than in the first transistors 100a, for example by an extra 15 nm. This accounts for forming extra transistor channels 204 a in the second transistors 100b compared to the first transistors 100a. In this way, after the epitaxially growing to form the S/D features 204b, the S/D features 204b is grown to have a greater volume in the second transistors 100b than in the first transistors 100a. When forming P-type FETs, the greater volume also improve strain and stress effects for better DC performance. After forming the S/D features 204b, an interlayer dielectric (ILD) layer 900 may be formed over the S/D features 204b. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK, polyimide, other low-k dielectric material, or combinations thereof

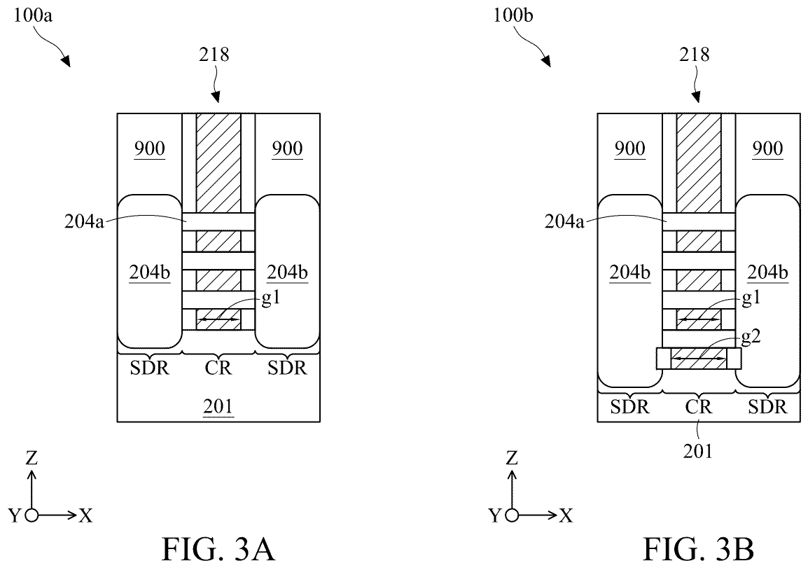

FIGS. 3A-3B illustrate cross-sectional views of a semiconductor structure 100 having transistors 100a and 100b of varied gate configurations while maintaining a same or similar effective channel width, according to an embodiment of the present disclosure. FIGS. 3A-3B resembles FIGS. 2C-2D, and the similar features will not be described again for the sake of brevity. The difference is that due to possible worse critical dimension (CD) loading effects when forming deeper S/D trenches, the gate structures 218 formed in second transistors 100b may not have uniform gate widths. For example, the bottommost portion of the gate structure 218 may have a gate width g2 greater than other portions of the gate structure 218 having the gate width g1. In an embodiment, the gate width g2 ranges between about 17 nm to about 20 nm. In an embodiment, the ratio of the gate width g1 to the channel width w2 ranges between about 0.5 to about 2. In an embodiment, the ratio of the gate width g2 to the channel width w2 ranges between about 0.6 to about 2.5. In some cases, worse loading effects may result in quality issues. As such, there is a tradeoff between forming first transistors 100a with uniform gate widths g1 but taking up a bigger cell area, versus forming second transistors 100b with nonuniform gate widths (e.g., bottom portion having gate width g2 greater than gate width g1) but reducing cell area. This may lead to forming semiconductor structures 100 having both first transistors 100a in a first cell 200a and second transistors 100b in a second cell 200b.

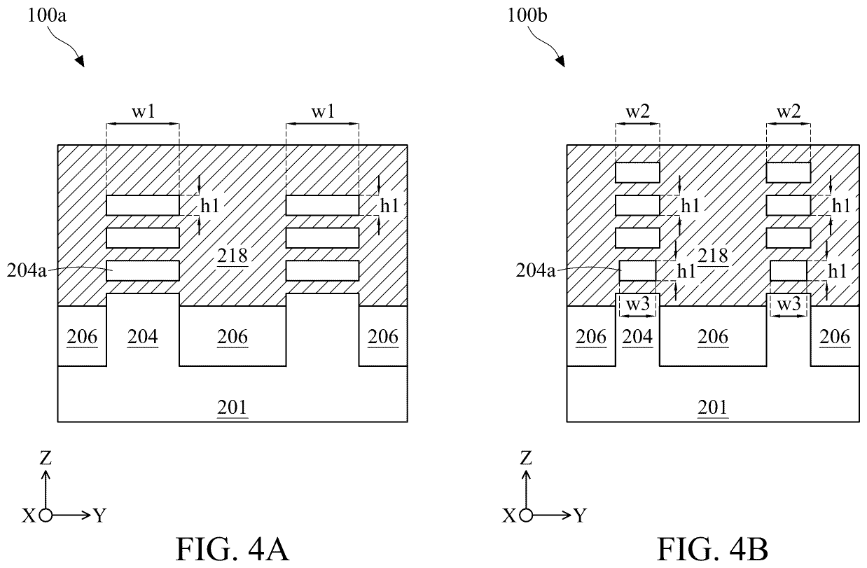

FIGS. 4A-4B illustrate cross-sectional views of a semiconductor structure 100 having transistors 100a and 100b of varied channel configurations while maintaining a same or similar effective channel width, according to an embodiment of the present disclosure. FIGS. 4A-4B resembles FIGS. 2A-2B, and the similar features will not be described again for the sake of brevity. The difference is that due to possible worse critical dimension (CD) loading effects when forming deeper S/D trenches, the transistor channels 204a formed in second transistors 100b may not have uniform channel widths. For example, the bottommost transistor channel 204a may have a channel width w3 smaller than other transistor channels 204a having the channel width w2. This may occur due to a greater etching time at the bottommost transistor channel compared to the rest of the channels during the channel release stage. The channel release stage is a stage of semiconductor manufacturing that forms suspended semiconductor channels by removing interposers in the channel region. The interposers may be removed by wet etch such as through HF solution. The wet solution may sit at the bottom regions longer than the top regions, causing the unequal channel widths. In some cases, these worse loading effects may result in quality issues. As such, there is a tradeoff between forming first transistors 100a with uniform channel widths w1 but taking up a bigger cell area, versus forming second transistors 100b with nonuniform channel widths (e.g., bottom channel having channel width w3 smaller than channel width w2) but reducing cell area. This may lead to forming semiconductor structures 100 having both first transistors 100a in a first cell 200a and second transistors 100b in a second cell 200b.

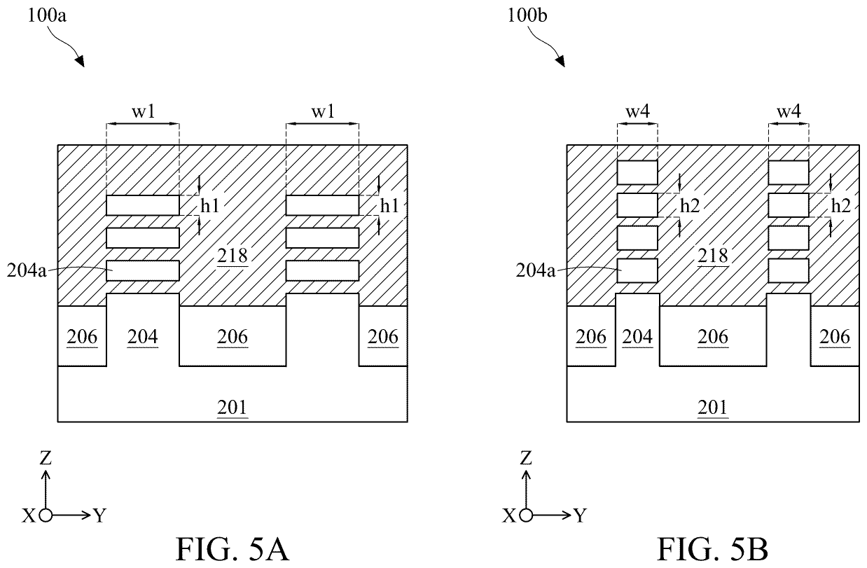

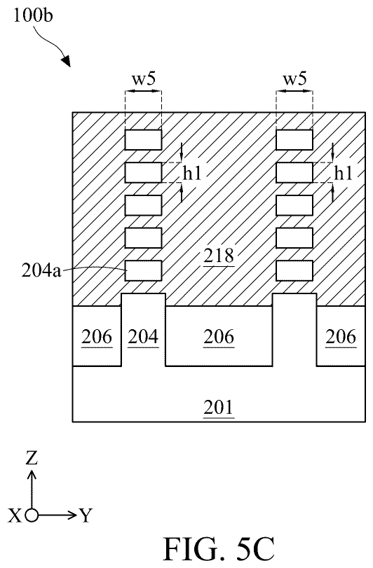

FIGS. 5A-5C illustrate cross-sectional views of a semiconductor structure 100 having transistors 100a and 100b of varied channel configurations while maintaining a same or similar effective channel width, according to an embodiment of the present disclosure. FIGS. 5A-5B resembles FIGS. 2A-2B, and the similar features will not be described again for the sake of brevity. The difference is that the transistor channels 204a do not have the same height h1 across transistors 100a and transistors 100b. As shown, the channels 204a in second transistors 100b may have a height h2 greater than the height h1. However, in this embodiment, to maintain a same effective channel width, the second transistors 100b may have a reduced channel width w4, which is smaller than the channel width w2 previously described. For example, the height h1 may be about 5 nm, the height h2 may be about 7 nm, the width w1 may be about 19 nm, and the width w4 may be about 11 nm. In this way, the first effective channel width may equal 144 nm (i.e., 2(5+19)*3), and the second effective channel width may also equal 144 nm (i.e., 2(7+11)*4). Compared to the embodiment of FIG. 2B, by increasing channel height to height h2, the second transistors 100b in FIG. 5B may achieve an even greater reduction in cell height due to an even lower channel width w4.

FIG. 5C illustrates another embodiment of second transistors 100b. In this embodiment, instead of increasing by one transistor channel to reduce cell size, the second transistors 100b is increased by two transistor channels (e.g., increasing from four to five transistor channels). The channels 204a in second transistors 100b may still have a height h1. However, in this embodiment, to maintain a same effective channel width, the second transistors 100b may have an even more reduced channel width w5, which is smaller than the channel width w2 previously described. For example, the height h1 may be about 5 nm, the width w1 may be about 19 nm, and the width w5 may be about 9 nm. In this way, the first effective channel width may equal 144 nm (i.e., 2(5+19)*3), and the second effective channel width may equal 140 nm (i.e., 2(5+9)*5). As such, the second effective channel width is substantially equal (within 5%) to the first effective channel width. Compared to the embodiment of FIG. 2B, by further increasing the number of transistor channels 204a, the second transistors 100b in FIG. 5B may achieve an even greater reduction in cell height due to an even lower channel width w5.

Although not shown, in further embodiments, the second transistors 100b may have even greater amounts of transistor channels 204a, such as greater than five but less than ten. Each increase in transistor channels 204a may require increasing S/D trench etch and/or increasing device height in the z direction. By increasing device height in the z direction, device cell height in the lateral direction is proportionally reduced. However, in some cases, having greater than ten transistor channels 204a would excessively reduce transistor channel widths (i.e., channel widths would be too narrow to keep a same or substantially uniform effective channel width across device regions). In these cases, the second transistors 100b will have no more than ten transistor channels 204a. In an embodiment, a ratio of the effective channel width to the number of transistor channels N is greater than 15 (e.g., limited by a maximum effective channel width of 160 nm and a maximum number of transistor channels of 10).

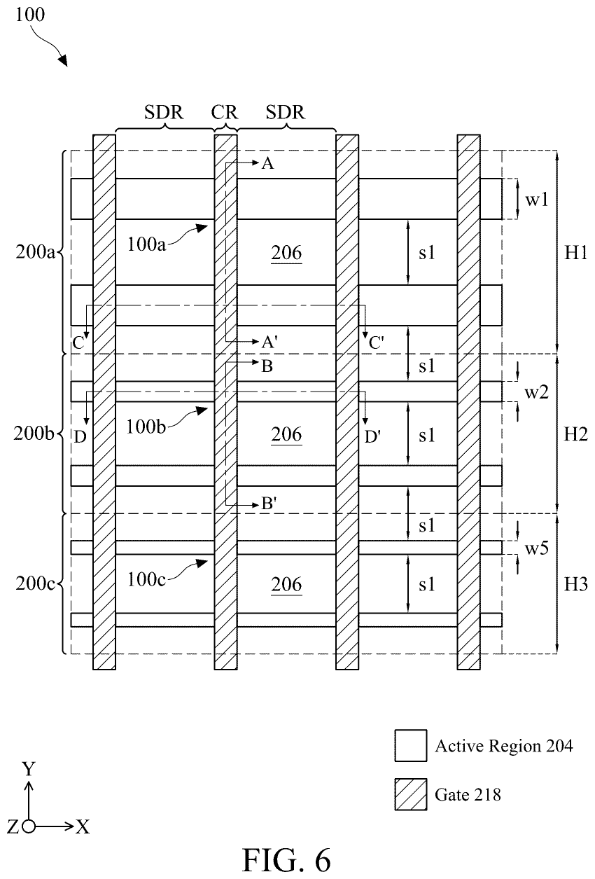

FIG. 6 illustrates a semiconductor structure 100 with cells 200a, 200b, and 200c of varied cell heights while maintaining a same or similar effective channel width, according to another embodiment of the present disclosure. FIG. 6 illustrate similar features as FIG. 1, and the similar features will not be described again for the sake of brevity. The difference is in the addition of a third cell 200c comprising third transistors 100c. The third transistors 100c are transistors with channel widths that are even more narrow than the second transistors 100b. To maintain same or similar effective channel widths, the third transistors 100c have a greater number of transistor channels than the second transistors 100b. For example, if the second transistors 100b have four transistor channels (see FIG. 2B), the third transistors 100c may have five transistor channels (see FIG. 5C). In the embodiment shown, the third cell 200c is adjacent the second cell 200b along the y direction. In other embodiments, the second cell 200b and third cell 200c may be interposed by other device regions. In the third cell 200c, each of the active regions 204 are spaced apart by the spacing s1 along the y direction. Further, the edge active regions 204 in the second and the third cells 200b and 200c may also be spaced apart by the same spacing s1.

As previously described, the first cell 200a is defined by a cell height H1 along the y direction, and the second cell 200b is defined by a cell height H2 along the y direction. Notably, the cell height H1 is greater than the cell height H2. This is because while the spacing s1 is the same between adjacent active regions 204, the active regions 204 in the first cell 200a has a greater channel width w1 along the y direction, while the active regions 204 in the second cell 200b has a smaller channel width w2 along the y direction. Similarly, the third cell 200c is defined by a cell height H3 along the y direction. Notably, the cell height H2 is greater than the cell height H3. This is because while the spacing s1 is the same between adjacent active regions 204, the active regions 204 in the second cell 200a has a greater channel width w2 along the y direction, while the active regions 204 in the third cell 200b has a smaller channel width (e.g., w5) along the y direction. For example, comparing between the second cell 200b and the third cell 200c, the second cell 200b comprises two wider active regions 204 extending along the x direction, and the third cell 200c comprises two narrower active regions 204 extending along the x direction. In this way, the cell height H2 is defined as two times the width w2 of the wider active regions 204 plus two times the spacing s1, and the cell height H3 is defined as two times the width w5 of the narrower active regions 204 plus two times the spacing s1.

In the present embodiment, the second transistors 100b have four transistor channels 204a and the third transistors 100c have five transistor channels 204a. Referring to the second cell 200b, in an embodiment, the spacing s1 may be about 46 nm, the wider active regions 204 may be about 13 nm in width, for a cell height H2 of about 118 nm. Referring to the third cell 200c, in an embodiment, the spacing s1 may be about 46 nm, the narrower active regions 204 may be about 9 nm in width, for a cell height H3 of about 110 nm. In an embodiment, a ratio of the second cell height H2 to the third cell height H3 may be greater than about 1.1 for meaningful total device cell size reduction (when converting some of the first cells 200a or second cells 200b into the third cells 200c). As explained herein, the total device cell size may be reduced while maintaining (or improving) device performance by converting one or more first cells 200a and/or second cells 200b into one or more third cells 200c.

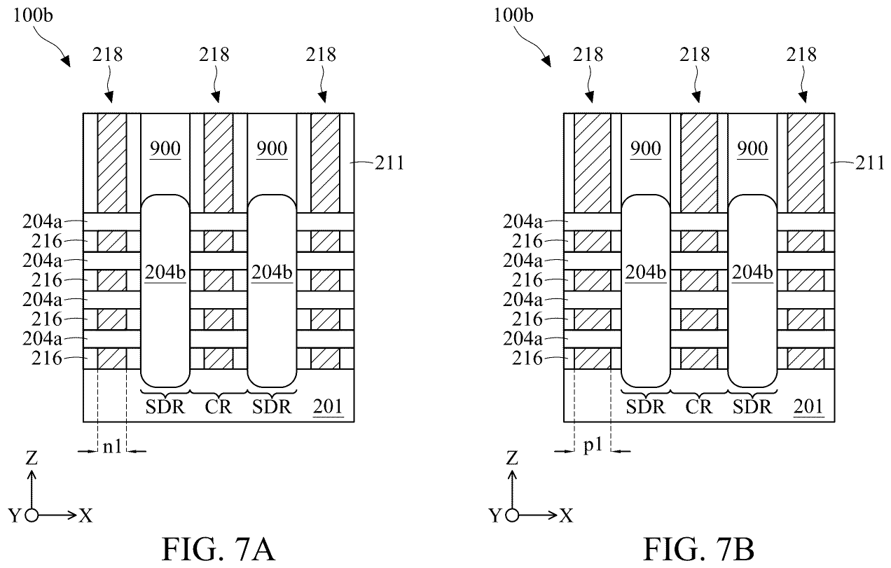

FIGS. 7A-7B illustrate cross-sectional views of a semiconductor structure 100 having second transistors 100b of varied gate configurations for an N-type and a P-type FET, according to an embodiment of the present disclosure. FIG. 7A illustrate an N-type FET having four transistor channels 204a wrapped around by a gate structure 218 with a gate width n1. FIG. 7B illustrate a P-type FET having four transistor channels 204a wrapped around by a gate structure 218 with a gate width p1. In the embodiment shown, the gate width p1 is greater than the gate width n1.

Still referring to FIGS. 7A-7B, in both the N-type and P-type FETs, there may be a same (or substantially same) effective channel width (e.g., channel width w2) for balancing DC performance and gate control as previously described. However, in the present embodiment, additional selective tuning is possible to further improve gate control and to lower effective capacitance while keeping the same effective channel width. In the present embodiment, the gate width n1 of the gate structure 218 in the N-type FET may be decreased and/or the inner spacer width of the inner spacers 216 may be increased (e.g., gate width n1 is less than the gate width g1 previously described for the first transistors 100a). In this way, there is better gate isolation leading to lower effective capacitance and improved gate control. However, for the P-type FET, a similar gate width lowering may not be done due to P-type FETs being more sensitive to DC characteristics changes than N-type FETs. That is, decreasing gate width p1 may adversely affect DC gain performance. As such, the gate width p1 may remain at the same width as the gate width g1 previously described for the first transistors 100a. In some cases, the gate width p1 may increase to a gate width greater than the gate width g1. In an embodiment, the gate width n1 ranges between about 14 nm to about 16 nm and the gate width p1 ranges between about 16 nm to about 19 nm.

Although not limiting, the present disclosure offers advantages for GAA devices. One example advantage is to form the GAA devices with extra channel layers and reducing channel width to reduce overall cell size. Another example advantage is to maintain a same effective channel width between the GAA devices with and without the extra channel layers for performance uniformity. Another example advantage is to strategically choose which GAA devices to convert to having extra channel layers based on tradeoffs between reducing cell size and loading effects. Another example advantage is to further tune effective capacitance between N-type and P-type FETs by adjusting gate width.

One aspect of the present disclosure pertains to a semiconductor structure. The semiconductor structure includes a first cell having first active regions extending lengthwise along a first direction; a second cell having second active regions extending lengthwise along the first direction; and gate structures wrapping around transistor channels of the first and the second active regions to form first transistors and second transistors, respectively, the gate structures extend lengthwise across the first and the second cells along a second direction perpendicular to the first direction. Each of the first transistors include a smaller number of transistor channels than each of the second transistors, and each of the first transistors has a greater channel width than each of the second transistors.

In an embodiment, the first cell has a first cell height along the second direction, the second cell has a second cell height along the second direction, and the first cell height is greater than the second cell height. In a further embodiment, a first spacing between the first active regions is substantially the same as a second spacing between the second active regions along the second direction. In a further embodiment, a third spacing between the first and the second active regions is substantially the same as the first spacing.

In an embodiment, the first transistors have a first effective channel width defined by a perimeter around a first transistor channel multiplied by the number of first transistor channels in the first transistors, the second transistors have a second effective channel width defined by a perimeter around a second transistor channel multiplied by the number of second transistor channels in the second transistors, and the first and the second effective channel widths are substantially the same.

In an embodiment, each the first transistors include three transistor channels, and each of the second transistors include four transistor channels. In a further embodiment, each of the transistor channels in the first transistors have a first width and a first height, each of the transistor channels in the second transistors have a second width and a second height, where the first width is greater than the second width, and the first height is substantially the same as the second height.

In an embodiment, each of the gate structures have substantially a same gate width that wraps around the transistor channels of the first and the second active regions. In an embodiment, a ratio of the first width to the second width ranges between about 1.35 to about 1.55.

In an embodiment, the first transistors include first source/drain (S/D) epitaxial features adjacent the transistor channels of the first transistors, the second transistors include second S/D epitaxial features adjacent the transistor channels of the second transistors, and the second S/D epitaxial features is greater in volume than the first S/D epitaxial features.

Another aspect of the present disclosure pertains to a semiconductor structure. The semiconductor structure includes a first transistor having first transistor channels wrapped around by first gate structures and first source/drain (S/D) features adjacent each of the first transistor channels. The first transistor has a first effective channel width defined by a perimeter around one of the first transistor channels multiplied by the number of transistor channels in the first transistor, where a ratio of the first effective channel width to the number of transistor channels in the first transistor is greater than 15. The first transistor has four transistor channels, and a channel width to a channel height of one of the first transistor channels has a ratio less than 3. In an embodiment, the ratio of the channel width to the channel height ranges between about 2.4 to about 2.8.

In an embodiment, the semiconductor structure further includes a second transistor having second transistor channels wrapped around by second gate structures and second source/drain (S/D) features adjacent each of the second transistor channels. The second transistors has a second effective channel width defined by a perimeter around one of the second transistor channels multiplied by the number of transistor channels in the second transistor. A ratio of the first effective channel width to a number of transistor channels in the first transistor is greater than 1. The second transistor has a different number of transistor channels from the first transistor. In an embodiment, the second transistor includes three transistor channels.

In an embodiment, the first transistor channels have a first channel width and a first channel height, the second transistor channels have a second channel width and a second channel height, where the first channel width is different from the second channel width, and the first channel height is different from the second channel height.

In an embodiment, each of the first and the second gate structures have substantially a same gate width that wraps around the first and the second transistor channels.

Another aspect of the present disclosure pertains to a semiconductor structure. The semiconductor structure includes first active regions extending lengthwise along a first direction; second active regions extending lengthwise along the first direction; and gate structures wrapping around transistor channels of the first and the second active regions to form first transistors and second transistors, respectively, the gate structures extend lengthwise along a second direction perpendicular to the first direction. Each of the first transistors include three transistor channels and each of the second transistors include four transistor channels. Each of the first transistors has a first width, each of the second transistors has a second width, and the first width is greater than the second width.

In an embodiment, the first transistors have a first effective channel width defined by a perimeter around one of the first transistor channels multiplied by three, the second transistors have a second effective channel width defined by a perimeter around one of the second transistor channels multiplied by four, and the first and the second effective channel widths are substantially the same.

In an embodiment, a spacing between adjacent first active regions and a spacing between adjacent second active regions are about the same along the second direction.

In an embodiment, each of the gate structures have substantially a same gate width that wraps around the transistor channels of the first and the second active regions.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first cell having first active regions extending lengthwise along a first direction;
a second cell having second active regions extending lengthwise along the first direction; and
gate structures wrapping around transistor channels of the first and the second active regions to form first transistors and second transistors, respectively, the gate structures extend lengthwise across the first and the second cells along a second direction perpendicular to the first direction,
wherein each of the first transistors include a smaller number of transistor channels than each of the second transistors, and each of the first transistors has a greater channel width than each of the second transistors.

2. The semiconductor structure of claim 1, wherein the first cell has a first cell height along the second direction, the second cell has a second cell height along the second direction, and the first cell height is greater than the second cell height.

3. The semiconductor structure of claim 2, wherein a first spacing between the first active regions is substantially the same as a second spacing between the second active regions along the second direction.

4. The semiconductor structure of claim 3, wherein a third spacing between the first and the second active regions is substantially the same as the first spacing.

5. The semiconductor structure of claim 1, wherein the first transistors have a first effective channel width defined by a perimeter around a first transistor channel multiplied by the number of first transistor channels in the first transistors, the second transistors have a second effective channel width defined by a perimeter around a second transistor channel multiplied by the number of second transistor channels in the second transistors, and the first and the second effective channel widths are substantially the same.

6. The semiconductor structure of claim 1, wherein each the first transistors include three transistor channels, and each of the second transistors include four transistor channels.

7. The semiconductor structure of claim 6, wherein each of the transistor channels in the first transistors have a first width and a first height, each of the transistor channels in the second transistors have a second width and a second height, wherein the first width is greater than the second width, and the first height is substantially the same as the second height.

8. The semiconductor structure of claim 7, wherein each of the gate structures have substantially a same gate width that wraps around the transistor channels of the first and the second active regions.

9. The semiconductor structure of claim 7, wherein a ratio of the first width to the second width ranges between about 1.35 to about 1.55.

10. The semiconductor structure of claim 1, wherein the first transistors include first source/drain (S/D) epitaxial features adjacent the transistor channels of the first transistors, the second transistors include second S/D epitaxial features adjacent the transistor channels of the second transistors, and the second S/D epitaxial features is greater in volume than the first S/D epitaxial features.

11. A semiconductor structure, comprising:
a first transistor having first transistor channels wrapped around by first gate structures and first source/drain (S/D) features adjacent each of the first transistor channels, wherein the first transistor has a first effective channel width defined by a perimeter around one of the first transistor channels multiplied by the number of transistor channels in the first transistor, wherein a ratio of the first effective channel width to the number of transistor channels in the first transistor is greater than 15,
wherein the first transistor has four transistor channels, and a channel width to a channel height of one of the first transistor channels has a ratio less than 3.

12. The semiconductor structure of claim 11, wherein the ratio of the channel width to the channel height ranges between about 2.4 to about 2.8.

13. The semiconductor structure of claim 11, further comprising:
a second transistor having second transistor channels wrapped around by second gate structures and second source/drain (S/D) features adjacent each of the second transistor channels,
wherein the second transistors has a second effective channel width defined by a perimeter around one of the second transistor channels multiplied by the number of transistor channels in the second transistor, wherein a ratio of the first effective channel width to a number of transistor channels in the first transistor is greater than 15
wherein the second transistor has a different number of transistor channels from the first transistor.

14. The semiconductor structure of claim 13, wherein the second transistor includes three transistor channels.

15. The semiconductor structure of claim 13, wherein the first transistor channels have a first channel width and a first channel height, the second transistor channels have a second channel width and a second channel height, wherein the first channel width is different from the second channel width, and the first channel height is different from the second channel height.

16. The semiconductor structure of claim 13, wherein each of the first and the second gate structures have substantially a same gate width that wraps around the first and the second transistor channels.

17. A semiconductor structure, comprising:
first active regions extending lengthwise along a first direction;
second active regions extending lengthwise along the first direction; and
gate structures wrapping around transistor channels of the first and the second active regions to form first transistors and second transistors, respectively, the gate structures extend lengthwise along a second direction perpendicular to the first direction,
wherein each of the first transistors include three transistor channels and each of the second transistors include four transistor channels,
wherein each of the first transistors has a first width, each of the second transistors has a second width, and the first width is greater than the second width.

18. The semiconductor structure of claim 17,
wherein the first transistors have a first effective channel width defined by a perimeter around one of the first transistor channels multiplied by three, the second transistors have a second effective channel width defined by a perimeter around one of the second transistor channels multiplied by four, and the first and the second effective channel widths are substantially the same.

19. The semiconductor structure of claim 17, wherein a spacing between adjacent first active regions and a spacing between adjacent second active regions are about the same along the second direction.

20. The semiconductor structure of claim 17, wherein each of the gate structures have substantially a same gate width that wraps around the transistor channels of the first and the second active regions.
